(19) United States
(12) Patent Application Publication
(10) Pub. No.: US 2024/0204008 A1
(43) Pub. Date: Jun. 20, 2024

(54) STRUCTURE AND METHOD TO FORM VIA TO BACKSIDE POWER RAIL WITHOUT SHORTING TO GATE TIP

(71) Applicant: International Business Machines Corporation, Armonk, NY (US)

(72) Inventors: Chanro Park, Clifton Park, NY (US); Ruilong Xie, Niskayuna, NY (US); Min Gyu Sung, Latham, NY (US); Julien Frougier, Albany, NY (US); Juntao Li, Cohoes, NY (US)

(21) Appl. No.: 18/066,671

(22) Filed: Dec. 15, 2022

(51) Int. Cl. H01L 27/12; H01L 21/768

(52) U.S. Cl. CPC H01L 27/1244; H01L 21/76831; H01L 27/1248; H01L 27/1266; H01L 21/31144

(57) ABSTRACT

One or more systems, devices and/or methods of fabrication provided herein relate to forming a via to backside power rail (VBPR) on a semiconductor device. According to one embodiment, a VBPR with a via spacer is formed before a late gate cut is performed to create a replacement metal gate (RMG), wherein the via spacer prevents a short circuit between the VBPR and the RMG. Further, the via spacer is removed in locations on the VBPR where a source/drain region is adjacent to the VBPR, allowing a conductive connection between the VBPR and the adjacent source/drain region.

### BACKGROUND

The subject disclosure relates to semiconductors and, more specifically, to forming a via to backside power rail.

Semiconductors are used in components of many electronic devices. As the semiconductor industry has grown, the density of devices on semiconductor chips has increased. Increasing density and decreasing spacing rules for semiconductor chips, down to the single-digit nanometer scale, can cause unwanted interactions between the signal layer and power layer, such as shorting and parasitic capacitance. Some designs use buried power rails and/or air gaps to address the unwanted interactions, keeping the power rail in a separate portion of the chip from active regions and front end signal lines. However, with increasing demands of the semiconductor industry, such techniques still leave room for methods and structures that can minimize or eliminate these unwanted interactions and that can be easily implemented in the industry. Thus, systems and/or methods that can address this technical problem are needed.

The above-described background description is merely intended to provide a contextual overview regarding semiconductor devices and is not intended to be exhaustive.

### SUMMARY

The following presents a summary to provide a basic understanding of one or more embodiments described herein. This summary is not intended to identify key or critical elements, delineate scope of particular embodiments or scope of claims. Its sole purpose is to present concepts in a simplified form as a prelude to the more detailed description that is presented later. In one or more embodiments described herein, systems, computer-implemented methods, apparatus and/or computer program products that enable forming an airgap in a semiconductor device are discussed.

According to an embodiment, a semiconductor device is provided. The semiconductor device can comprise a via to backside power rail (VBPR), wherein the via is located between the active regions of nanosheets (NS's) of a first field effect transistor (FET) and a second FET. The semiconductor device can further comprise at least one gate connected to one or both of the NS's, and a via spacer which separates the VBPR from the gates. Such embodiment of the semiconductor device can provide a number of advantages, including that the via spacer prevents shorting between the VBPR and adjacent gates, and prevents or maintains parasitic capacitance in the semiconductor device below a threshold.

In some embodiments, the FET's can additionally comprise one or more source regions and drain regions, wherein the source regions and drain regions can be connected to a contact on a frontside of the device and FET, and wherein no via spacer separates the VBPR from the source/drain region. Such embodiment of the semiconductor device can provide a number of advantages, including wiring an FEOL source/drain (S/D) region to a VBPR while preventing shorting between the VBPR and adjacent gates.

According to another embodiment, a method for fabricating a semiconductor device is provided. The method can comprise starting with a substrate with FET's with NS's and conventional source/drain structures and dummy gate structures, creating a VBPR before creating a gate cut for a replacement metal gate, wherein both the VBPR and gate cut are located between a first NS and a second NS, and the VBPR and gate cut do not overlap. The method can further comprise forming a via spacer around all lateral sides of the VBPR, preventing shorting between the VBPR and adjacent gates. The method can further comprise removing portions of the via spacer which are adjacent to a source or drain region on one of the FET's, enabling a conductive connection between the VBPR and adjacent FET source and drain regions. The method can further comprise bonding a carrier wafer to the current front side of the semiconductor device, flipping the semiconductor device so that its original silicon substrate is now on the front side for fabrication purposes, and creating a back side power rail connected to a BEOL. Such embodiment of the method can provide a number of advantages, including that shorting and parasitic capacitance between the VBPR and at least a first gate of the semiconductor device can be minimized or prevented, and that surface area of the front side of the semiconductor ship is freed up by placing the power delivery network on the back side (BSPDN), allowing the front side surface area of the semiconductor chip to be reduced, or alternatively to hold more structures and functionality.

### BRIEF DESCRIPTION OF THE DRAWINGS

FIG. 1 illustrates an example, non-limiting top view of a semiconductor device in accordance with one or more embodiments described herein.

FIG. 2 illustrates a top view of a prior art semiconductor device with a via that is prone to shorting with one or more gate tips.

FIG. 3A illustrates an example, non-limiting top view of a starting substrate, in accordance with one or more embodiments described herein.

FIG. 3B illustrates example, non-limiting cross-sectional views of a starting substrate in accordance with one or more embodiments described herein.

FIG. 4 illustrates example, non-limiting cross-sectional views of a step comprising depositing a lithography stack mask in preparation for lithography in a semiconductor device fabrication process in accordance with one or more embodiments described herein.

FIG. 5 illustrates example, non-limiting cross-sectional views of a step comprising reactive ion etching to create a trench, and removing the lithography stack mask in a semiconductor device fabrication process in accordance with one or more embodiments described herein.

FIG. 6 illustrates example, non-limiting cross-sectional views of a step comprising adding a via spacer layer and removing non-lateral portions of the via spacer layer in a semiconductor device fabrication process in accordance with one or more embodiments described herein.

FIG. 7 illustrates example, non-limiting cross-sectional views of a step comprising metallizing the power via trench and capping the power via with silicon dioxide in a semiconductor device fabrication process in accordance with one or more embodiments described herein.

FIG. 8 illustrates example, non-limiting cross-sectional views of a step comprising removing sacrificial material in preparation for replacement metal gate formation in a semiconductor device fabrication process in accordance with one or more embodiments described herein.

FIG. 9 illustrates example, non-limiting cross-sectional views of a step comprising depositing dielectric material to form a replacement metal gate, and capping the replacement metal gate with nitride in a semiconductor device fabrication process in accordance with one or more embodiments described herein.

FIG. 10 illustrates example, non-limiting cross-sectional views of a step comprising depositing a lithography stack mask in preparation for lithography in a semiconductor device fabrication process in accordance with one or more embodiments described herein.

FIG. 11A illustrates example, non-limiting cross-sectional views of a step comprising forming a late gate cut and removing the lithography stack mask in a semiconductor device fabrication process in accordance with one or more embodiments described herein.

FIG. 11B illustrates an example, non-limiting top view of a step comprising forming a late gate cut and removing the lithography stack mask in a semiconductor device fabrication process in accordance with one or more embodiments described herein.

FIG. 12 illustrates example, non-limiting cross-sectional views of a step comprising filling the gate cut with dielectric material such as silicon nitride, polishing and capping the semiconductor device with interlayer dielectric layer in a semiconductor device fabrication process in accordance with one or more embodiments described herein.

FIG. 13 illustrates example, non-limiting cross-sectional views of a step comprising depositing a lithography stack mask in preparation for lithography in a semiconductor device fabrication process in accordance with one or more embodiments described herein.

FIG. 14 illustrates example, non-limiting cross-sectional views of a step comprising reactive ion etching to expose source/drain contacts and a portion of the via spacer, and removing the lithography stack mask in a semiconductor device fabrication process in accordance with one or more embodiments described herein.

FIG. 15 illustrates example, non-limiting cross-section views of a step comprising removing the exposed portion of the spacer in a semiconductor device fabrication process in accordance with one or more embodiments described herein.

FIG. 16A illustrates example, non-limiting cross-sectional views of a step comprising gate contact patterning in a semiconductor device fabrication process in accordance with one or more embodiments described herein.

FIG. 16B illustrates an example, non-limiting top view of a source/drain contact patterning step in a semiconductor device fabrication process in accordance with one or more embodiments described herein.

FIG. 17 illustrates example, non-limiting cross-sectional views of a metallization step in a semiconductor device fabrication process in accordance with one or more embodiments described herein.

FIG. 18 illustrates example, non-limiting cross-section views of a step comprising forming a back end-of-line (BEOL) in a semiconductor device fabrication process in accordance with one or more embodiments described herein.

FIG. 19 illustrates example, non-limiting cross-sectional views of a step comprising wafer bonding, flipping the device, and grinding the new front side, in a semiconductor device fabrication process in accordance with one or more embodiments described herein.

FIG. 20 illustrates example, non-limiting cross-sectional views of a step comprising recessing a silicon layer and depositing an interlayer dielectric (ILD) in a semiconductor device fabrication process in accordance with one or more embodiments described herein.

FIG. 21 illustrates example, non-limiting cross-sectional views of a step comprising metallizing to form a back-end-of-line (BEOL) device and backside power rail (BSPR) in a semiconductor device fabrication process in accordance with one or more embodiments described herein. Being the last step, FIG. 21 also illustrates example, non-limiting cross-sectional views of a semiconductor device in accordance with one or more embodiments described herein, which may be paired with the top view shown in FIG. 1.

FIG. 22 illustrates a flow diagram of an example, non-limiting method in accordance with one or more embodiments described herein.

FIG. 23 illustrates a flow diagram of an additional example, non-limiting method in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Semiconductors are used in components of several electronic devices, such as high performance or low power logic devices, memories, etc. As the semiconductor industry has grown, the density of devices on semiconductor chips has increased. Increased density and decreasing spacing rules for semiconductor chips can cause conductive components to be extremely close to one another, in some cases resulting in misalignment and short circuits, for example power via-to-PC (gate) shorting in chips incorporating a nanosheet FET.

Existing art does not address the problem of misalignment and shorting between VBPR and PC or gate tips, or solutions for these problems. A prior art design as shown in FIG. 2 places a VBPR in the same location as a gate cut, causing the VBPR to be in very close proximity with multiple gates, making an unwanted short circuit possible. Using this prior art design, slight misalignment can make shorting between VBPR and a gate tip even more likely. Thus, methods and structures that can address one or more of the challenges discussed herein while being easy to detect, use and implement in the industry, can be desirable.

To that end, various embodiments herein relate to a unique structure and method of forming a semiconductor device that can have a number of advantages. For example, the various embodiments herein can comprise a semiconductor device that can be fabricated to comprise a silicon oxycarbide spacer between a power via of the semiconductor device and gate ends of a high-k metal gate (HKMG) of the semiconductor device. The via spacers can be formed such that the spacers can extend between the power via and one or more gate contacts of the semiconductor device, but spacers are not present between the power via and FEOL (front end-of-line) source/drain contacts, thereby preventing shorting between the one or more gate contacts and the power via, while enabling connection between the power via and FEOL S/D regions of the semiconductor device to a BSPR (backside power rail), by being connected to one or more other source/drain contacts. The various embodiments of the semiconductor device discussed herein can be applicable to electronic devices, such as high performance or low power logic devices, memories, etc.

The term “high-k,” as used herein, refers to a material having a relatively high dielectric constant (k) as compared to that of SiO₂, such as, for example, Hafnium Oxide (HfO₂). Metal gates comprise workfunction metals, such as Titanium nitride (TiN), Titanium carbide (TiC), Titanium aluminide (TiAl), TiAlC, etc., and conductive metal fills, such as Tungsten (W). S/D regions can be formed from in-situ epitaxial materials such as epitaxial Si, epitaxial SiGe, etc., and the doping type can be either n-type or p-type depending on the device polarity. Similarly, ILD layers can be formed by employing suitable deposition techniques.

In some embodiments, the via spacer can be formed from a dielectric material such as SiOₓC_{y} (silicon oxycarbide, also commonly referred to as SiOC). In some other embodiments, other dielectric materials can be used to form the via spacer.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

One or more embodiments described herein can employ hardware and/or software to solve problems that are highly technical, that are not abstract, and that cannot be performed as a set of mental acts by a human. For example, a human, or even thousands of humans, cannot efficiently, accurately and/or effectively form a silicon oxycarbide spacer between a power via and gate ends or contacts of a semiconductor device as the one or more embodiments described herein can enable this process. And, neither can the human mind nor a human with pen and paper form a silicon oxycarbide spacer between a power via and gate ends or contacts of a semiconductor device, as conducted by one or more embodiments described herein.

It should also be understood that when an element such as Silicon layer, etc. is referred to as being “on” or “over” another element, it can be directly on the other element or intervening elements can also be present. In contrast, when an element is referred to as being “directly on” or “directly over” another element, there are no intervening elements present. It should also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

These and other aspects and embodiments of the disclosed subject matter will now be described with respect to the drawings. It is to be appreciated that the words “semiconductor”, “semiconductor device” and “semiconductor chip” have been used interchangeably throughout this specification. Similarly, the words “gate/s” and “gate end/s” have been used interchangeably throughout this specification. It is to be further appreciated that individual cross-sectional views X, Y1 and Y2 of the semiconductor device are respectively identified as X, Y1 and Y2 in the figures. The cross-sectional views Y1 and Y2 are presented as viewed from the left side of the top views. The cross-sectional view X is presented as viewed from the bottom of the top views.

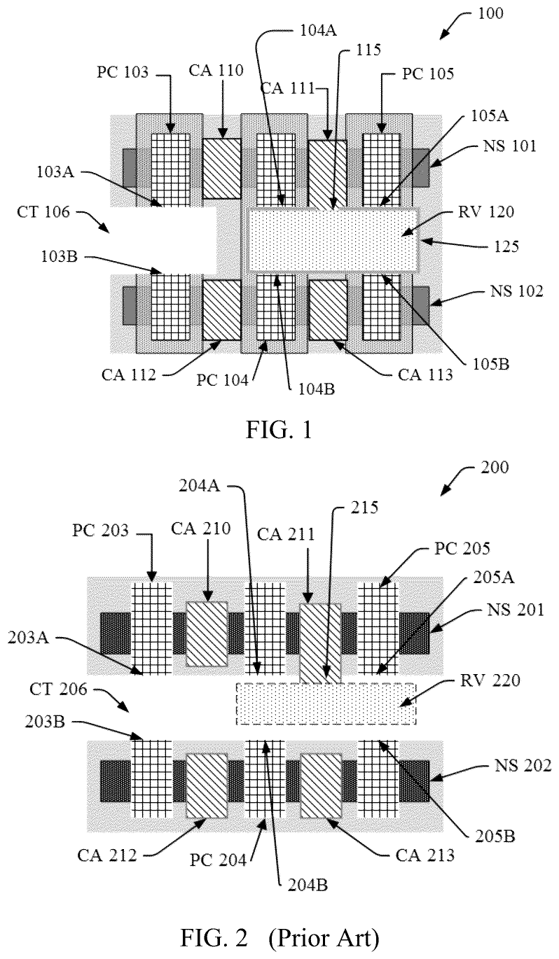

FIG. 1 illustrates an example, non-limiting top view 100 of a semiconductor device in accordance with one or more embodiments described herein.

In an embodiment, a semiconductor device can comprise two field effect transistors (FETs), multiple HKMGs with gate tips, source/drain contacts, a power via, and a liner. In FIG. 1, the nanosheets (NS's) are illustrated as NS 101 and NS 102. It is to be appreciated that a voltage source supply (VSS) backside power rail under cell boundary region near the NS's has been used here for illustration purposes, and the one or more embodiments discussed herein can work the same at the cell boundary between the NS's. Further, in FIG. 1, the HKMGs are identified as PC 103, PC 104 and PC 105, with gate tips identified as 103A and 103B located adjacent to a gate cut identified as CT 106, and gate tips identified as 104A 104B, 105A and 105B located adjacent to a power via identified as RV 120. The term “high-k,” as used herein, refers to a material having a relatively high dielectric constant (k) as compared to that of Silicon Dioxide (SiO₂), such as, for example, Hafnium Oxide (HfO₂).

Further, in FIG. 1, source/drain contacts are identified as CA 110, CA 111, CA 112 and CA 113. The power via RV 120 is surrounded by a via spacer identified as 125, on all sides of the power via except for in the area adjacent to a source/drain contact identified as 115.

FIG. 2 illustrates a top view 200 of a prior art semiconductor device having a high level design approach which places a VBPR, identified as RV 220, in a gate cut region, identified as CT 206. Many components of the semiconductor device shown in FIG. 2 are analogous to those shown in FIG. 1. Two NS's are illustrated as NS 201 and NS 202; HKMGs are identified as PC 203, PC 204 and PC 205, with gate tips identified as 203A, 203B, 204A, 204B, 205A and 205B located adjacent to a gate cut identified as CT 206; and source/drain contacts are identified as CA 210, CA 211 and CA 212. The source/drain contact identified as CA 211 is adjacent to the power via RV 220 at 215.

While the power via RV 220 shown in FIG. 2 is within the gate cut region CT 206, the power via is not intended to be adjacent to or close enough to any gate tips, such as those identified as 204A, 204B, 205A or 205B, so as to cause shorting. A tiny fabrication error can place the power via too close to or in contact with a gate tip, causing a short circuit, and making the semiconductor device unusable.

In addition, when fabricating a semiconductor device using the design of FIG. 2, precisely and successfully placing a source/drain contact CA 211 adjacent to the power via is very difficult, due to extremely close spacing rules and constraints, making it likely for the source/drain contact to touch a gate, and cause shorting.

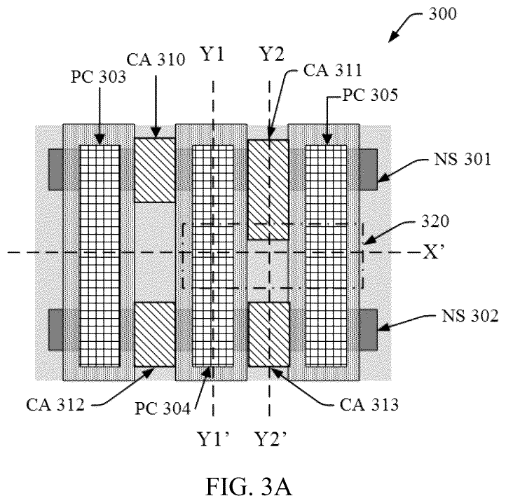

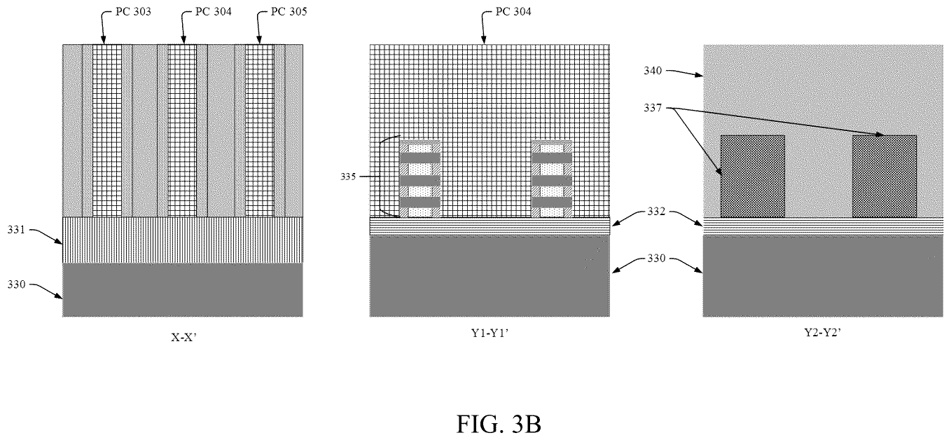

The method of formation of the semiconductor device comprising a via spacer (i.e., 125) laterally surrounding a power via (i.e., RV 120) except for power via regions adjacent to a source/drain contact of an FET (i.e., 115) can begin with a starting substrate as illustrated in FIGS. 3A and 3B. Top view 300 further illustrates locations X-X′, Y1-Y1′ and Y2-Y2′ representing cross-sectional views of the semiconductor device. The cross-sectional views X-X′, Y1-Y1′ and Y2-Y2′ are further elaborated in FIG. 3B and following. As noted earlier, the cross-sectional views Y1-Y1′ and Y2-Y2′ are presented as viewed from the left side of the top views. The cross-sectional view X-X′ is presented as viewed from the bottom side of the top views.

FIG. 3A illustrates an example, non-limiting top view 300 of a starting substrate in accordance with one or more embodiments described herein. Repetitive description of like elements and/or processes employed in respective embodiments is omitted for sake of brevity. The starting substrate has two NS's, identified as NS 301 and NS 302; dummy gates identified as PC 303, PC 304 and PC 305, and target areas for source/drain contacts identified as CA 310, CA 311, CA 312 and CA 313. A dot-dashed line 330 identifies the region where the power via trench will be located.

FIG. 3B illustrates three cross-sectional views X-X′, Y1-Y1′ and Y2-Y2′ of a starting substrate for the method in accordance with one or more embodiments described herein. Repetitive description of like elements and/or processes employed in respective embodiments is omitted for sake of brevity. In an embodiment, a semiconductor device can comprise a silicon substrate layer 330, shallow trench isolation (STI) layer 331, bottom dielectric isolation (BDI) layer 332, nanosheet (NS) stacks 335, dummy gates PC 303, PC 304 and PC 305, epitaxial source/drain (S/D) regions 337, and ILD layer 340 as illustrated by the cross-sectional views X-X′, Y1-Y1′ and Y2-Y2′ of the semiconductor device. Chemical metal planarization (CMP) is a removal process that has been performed to smooth the surface.

It is to be appreciated that in the top views and cross-sectional views illustrated in the figures, individual layers and regions of the semiconductor are represented by individual patterns and the patterns for the respective layers and regions of the semiconductor device are consistent throughout the top views and cross-sectional views. It is to be further appreciated that the patterns for the individual layers and regions of the semiconductor device are different for the cross-sectional views as opposed to the top views, for the purpose of simplicity of illustration. For example, the gate cut area (e.g., CT 106) is consistently illustrated in the top views without any pattern, whereas the gate cut area is illustrated with various patterns in the cross-sectional views.

It is to be appreciated that several layers and features of the semiconductor device illustrated in the cross-sectional views of FIG. 3B are also illustrated in cross-sectional views shown in other figures, although only some layers are discussed in detail for sake of brevity. Repetitive description of like elements and/or processes employed in respective embodiments is omitted for sake of brevity.

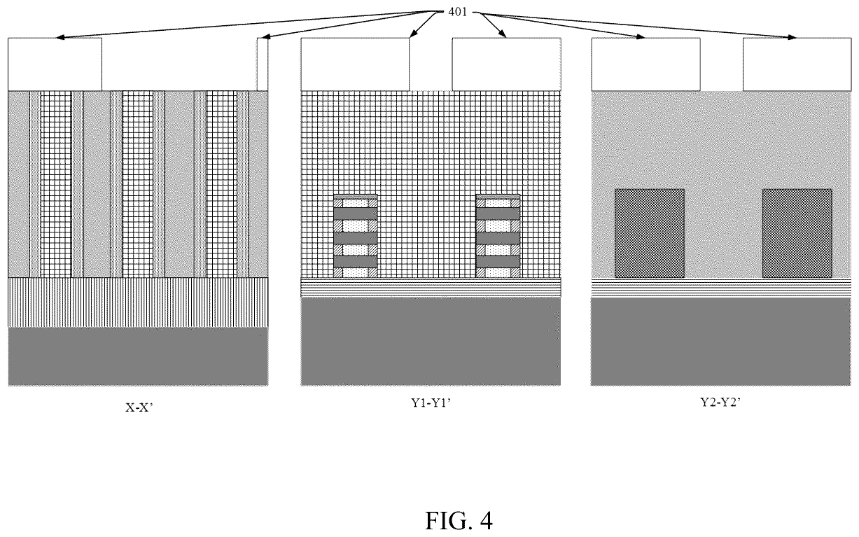

FIG. 4 illustrates example, non-limiting cross-sectional views of a step comprising depositing a lithography stack mask in preparation for reactive ion etching (RIE) in a semiconductor device fabrication process in accordance with one or more embodiments described herein. Repetitive description of like elements and/or processes employed in respective embodiments is omitted for sake of brevity. The lithography stack mask is identified as 401. A lithography stack, when referred to in this and other method steps, may comprise any combination of one or more photoresist layers and may include one or more additional layers, such as an optical planarization layer and an anti-reflective coating layer.

Deposition is any process that grows, coats, or otherwise transfers a material onto a substrate. Available technologies include, but are not limited to, dielectric spin-on, thermal oxidation, physical vapor deposition (PVD), chemical vapor deposition (CVD), electrochemical deposition (ECD), molecular beam epitaxy (MBE) and more recently, atomic layer deposition (ALD) among others.

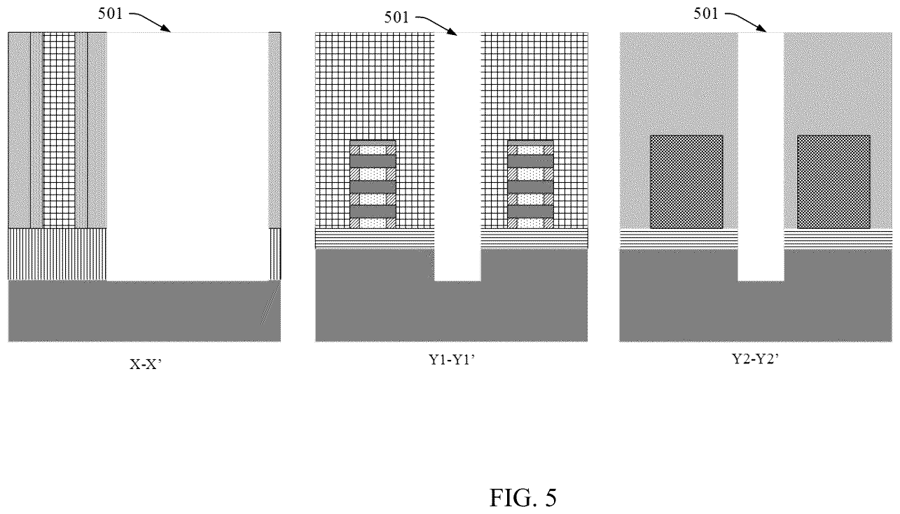

FIG. 5 illustrates example, non-limiting cross-sectional views of a step comprising non-selective RIE to create a trench for a power via, and removing the lithography stack mask 401 in a semiconductor device fabrication process in accordance with one or more embodiments described herein. Repetitive description of like elements and/or processes employed in respective embodiments is omitted for sake of brevity. The power via trench is identified as 501.

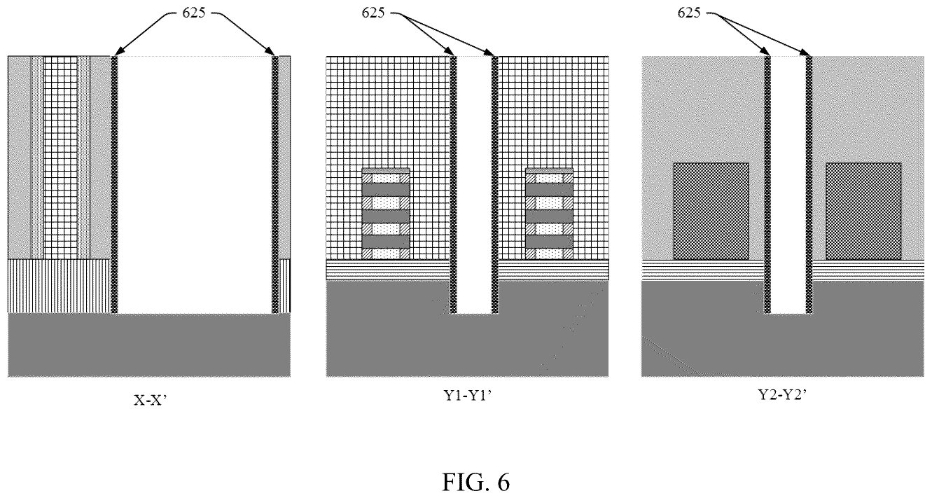

FIG. 6 illustrates example, non-limiting cross-sectional views of a step comprising forming one or more layers of silicon oxycarbide on lateral surfaces of the power via trench, to serve as a via spacer in a semiconductor device fabrication process in accordance with one or more embodiments described herein. Sub-steps not shown may include forming a silicon oxycarbide layer on all exposed surfaces of the semiconductor device, and removing portions of the silicon oxycarbide layer which are not on lateral surfaces of the power via trench. The silicon oxycarbide layer is identified as 625. Repetitive description of like elements and/or processes employed in respective embodiments is omitted for sake of brevity.

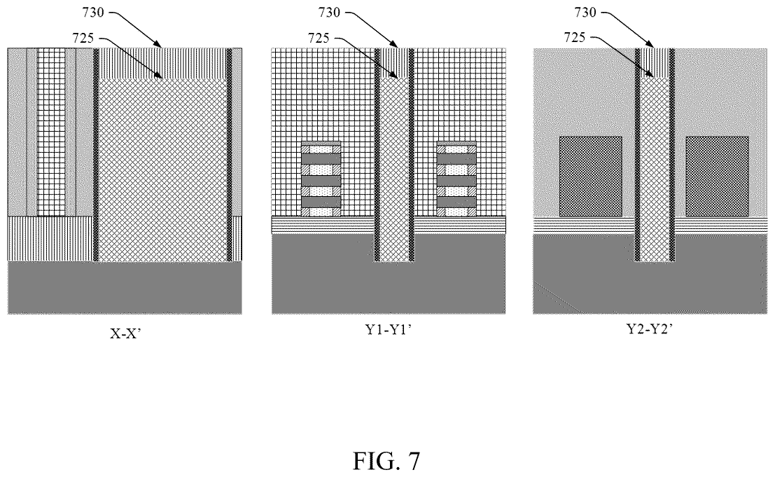

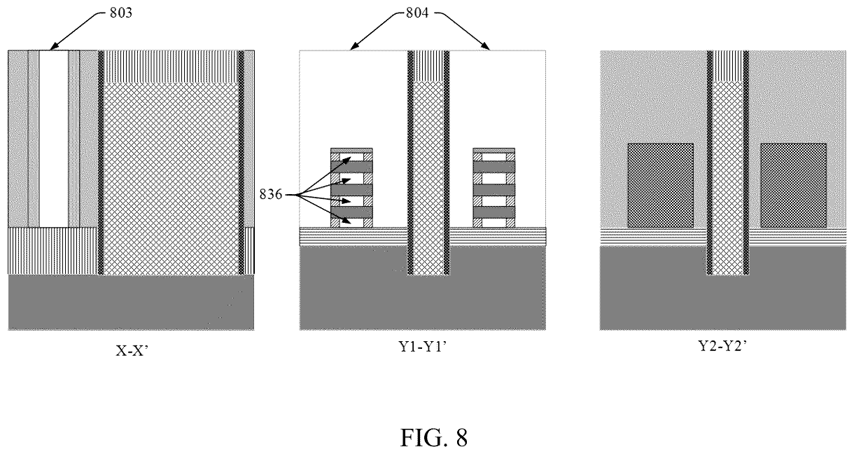

FIG. 7 illustrates example, non-limiting cross-sectional views of a metallization and capping step in a semiconductor device fabrication process in accordance with one or more embodiments described herein. Repetitive description of like elements and/or processes employed in respective embodiments is omitted for sake of brevity. The power trench is filled with metal, such as cobalt, ruthenium, copper, molybdenum, tungsten, rhodium or another metal, identified in FIG. 7 as 725. Sub-steps in the metallization process, such as over-filling the trench, CMP and controlling the recess of the metal layer, are well known and not shown. The metallized power via is then capped with a layer of silicon dioxide, identified as 730.

FIG. 8 illustrates example, non-limiting cross-sectional views of a step comprising removing a dummy gate and sacrificial SiGe layers of NS stacks in a semiconductor device fabrication process in accordance with one or more embodiments described herein. This step is in preparation for forming a replacement metal gate. The voids created by removal of the dummy gate are identified as 803 and 804. The remaining NS stacks are left with voids created by removal of the sacrificial SiGe, the voids being identified as 836. Repetitive description of like elements and/or processes employed in respective embodiments is omitted for sake of brevity.

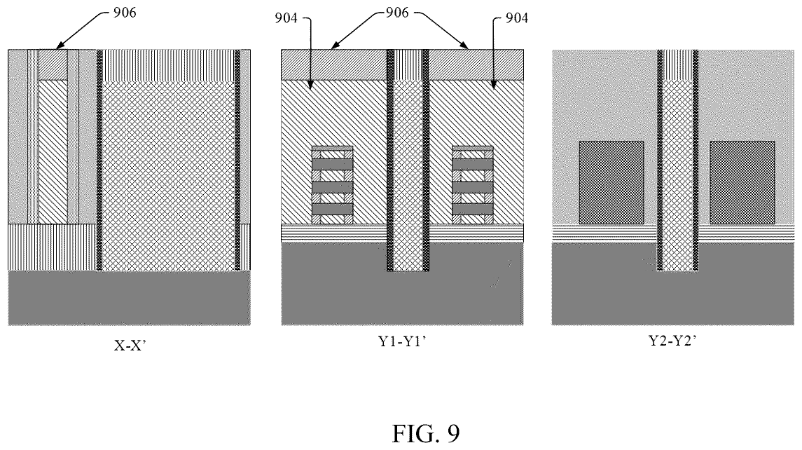

FIG. 9 illustrates example, non-limiting cross-sectional views of a metallization and capping step comprising several sub-steps, resulting in creation of high-k replacement metal gates, identified as 903 and 904. CMP is performed, and then the replacement metal gates are recessed and capped with a layer of silicon nitride, identified as 906. Repetitive description of like elements and/or processes employed in respective embodiments is omitted for sake of brevity.

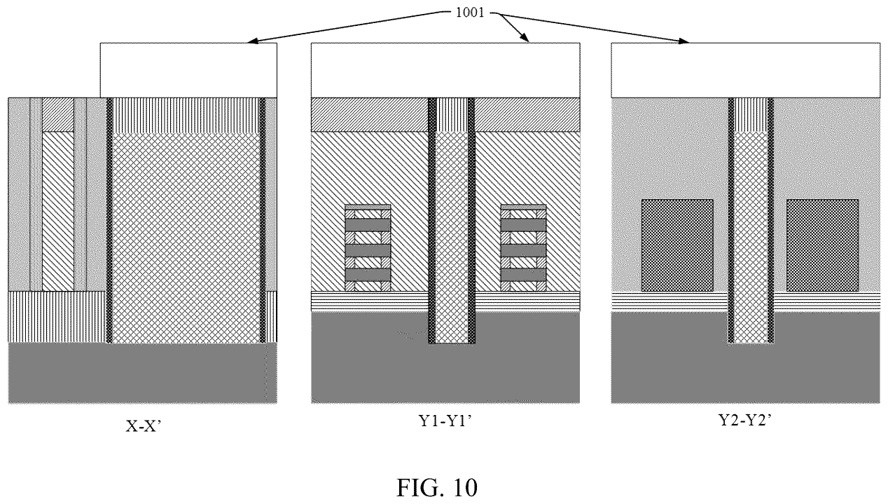

FIG. 10 illustrates example, non-limiting cross-sectional views of a step comprising depositing a lithography stack mask in preparation for reactive ion etching (RIE) in a semiconductor device fabrication process in accordance with one or more embodiments described herein. Repetitive description of like elements and/or processes employed in respective embodiments is omitted for sake of brevity. The lithography stack mask is identified as 1001.

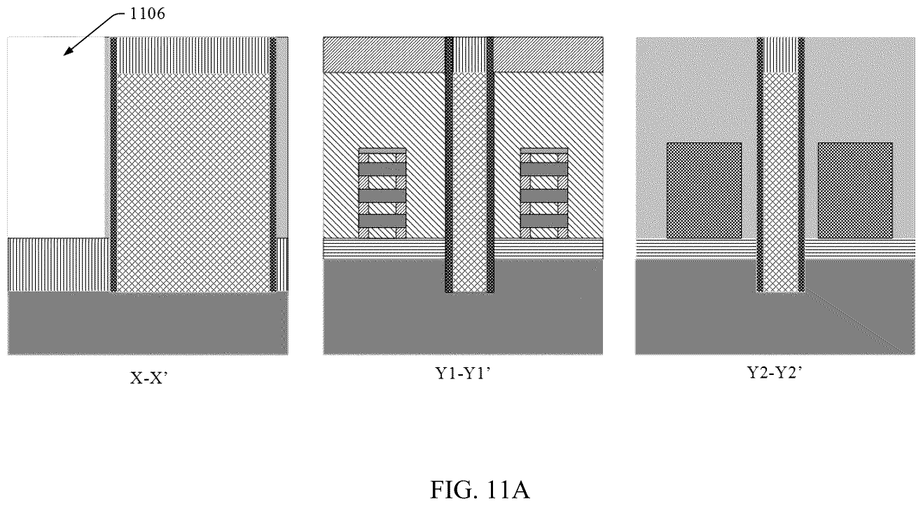

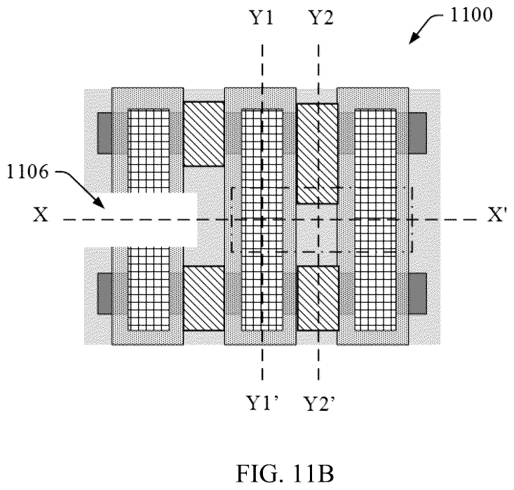

FIG. 11A illustrates example, non-limiting cross-sectional views of a step comprising non-selective RIE to create a gate cut, and removing the lithography stack mask 1001 in a semiconductor device fabrication process in accordance with one or more embodiments described herein. Repetitive description of like elements and/or processes employed in respective embodiments is omitted for sake of brevity. The void created by the gate cut is identified as 1106.

FIG. 11B illustrates an example, non-limiting top view 1100 of a step comprising non-selective RIE to create a gate cut, and removing the lithography stack mask 1001 in a semiconductor device fabrication process in accordance with one or more embodiments described herein. Repetitive description of like elements and/or processes employed in respective embodiments is omitted for sake of brevity. The void created by the gate cut is identified as 1106.

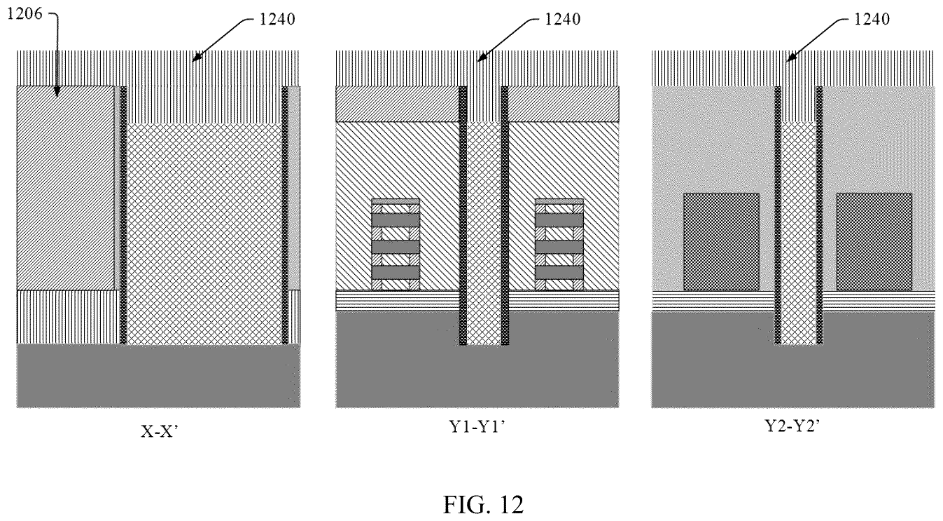

FIG. 12 illustrates example, non-limiting cross-sectional views of a step comprising filling the gate cut with dielectric material, polishing and capping the semiconductor device with interlayer dielectric layer in a semiconductor device fabrication process in accordance with one or more embodiments described herein. The dielectric material used to fill the gate cut can be silicon nitride, and is identified as 1206. The top layer is then polished, recessed and an ILD layer is deposited, which can be silicon dioxide, and is identified as 1240.

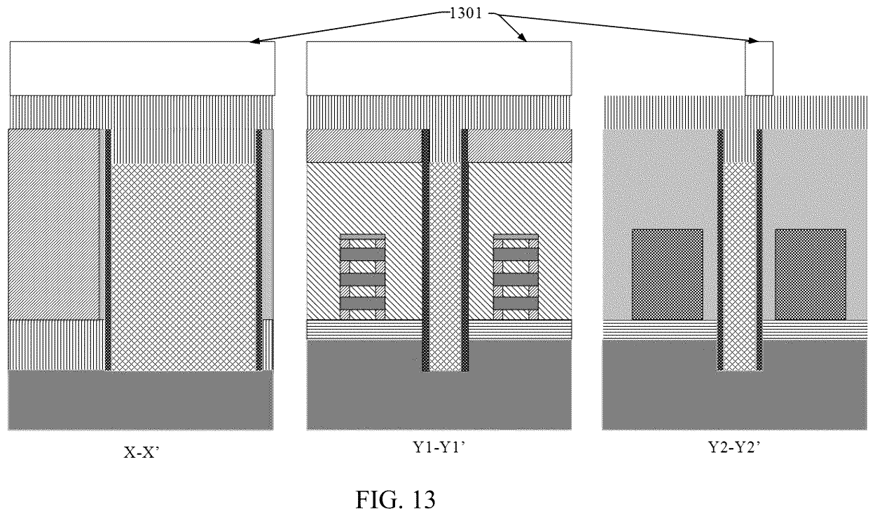

FIG. 13 illustrates example, non-limiting cross-sectional views of a step comprising depositing a lithography stack mask in preparation for reactive ion etching (RIE) in a semiconductor device fabrication process in accordance with one or more embodiments described herein. Repetitive description of like elements and/or processes employed in respective embodiments is omitted for sake of brevity. The lithography stack mask is identified as 1301.

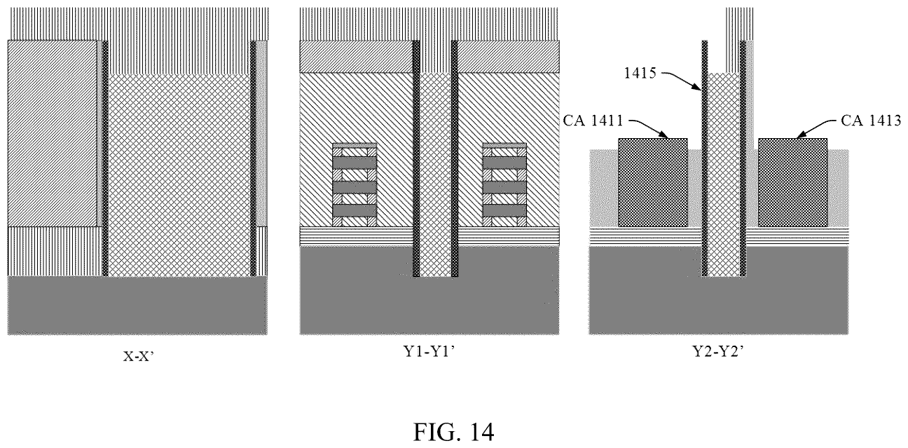

FIG. 14 illustrates example, non-limiting cross-sectional views of a patterning step in a semiconductor device fabrication process in accordance with one or more embodiments described herein. Repetitive description of like elements and/or processes employed in respective embodiments is omitted for sake of brevity. RIE removes ILD material to expose source/drain regions, as well as to expose a portion of the power via and via spacer which is adjacent to a source/drain region. The source/drain contacts are identified as CA 1411 and CA 1413, and the exposed via spacer is identified as 1415. The lithography stack mask 1301 is then removed.

As discussed in one or more embodiments herein, patterning is the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light. The exposed regions are then washed away by a developer solution. After etching or other processing, the remaining photoresist is removed. After transferring the pattern, the patterned photoresist is removed utilizing resist stripping processes, such as wet chemical clean or ashing. Ashing can be used to remove a photoresist material, amorphous carbon, or organic planarization (OPL) layer. Ashing is performed using a suitable reaction gas, for example, O₂, N₂, H₂/N₂, O₃, CF₄, or any combination thereof. Patterning also includes electron-beam lithography, nanoimprint lithography, and reactive ion etching.

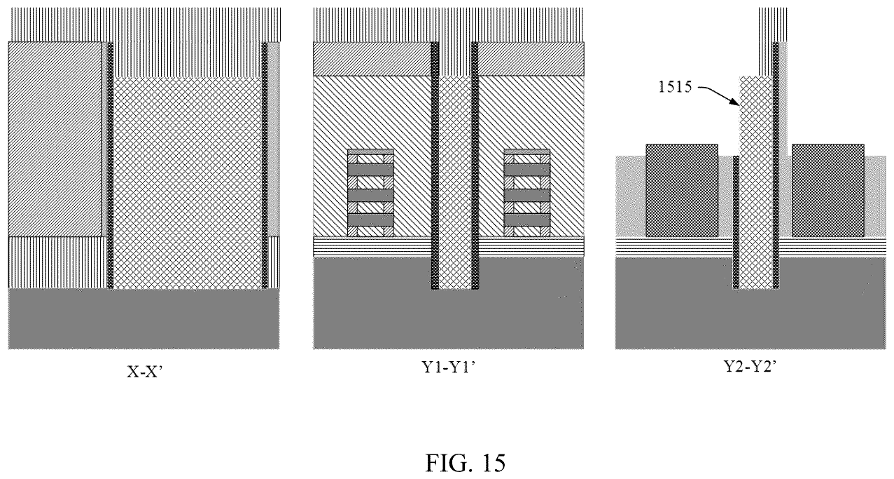

FIG. 15 illustrates example, non-limiting cross-sectional views of a via spacer removal step in a semiconductor device fabrication process in accordance with one or more embodiments described herein. Repetitive description of like elements and/or processes employed in respective embodiments is omitted for sake of brevity. The exposed portion of via spacer can be removed using plasma ashing and wet chemistry methods. The newly exposed portion of the power via is identified as 1515.

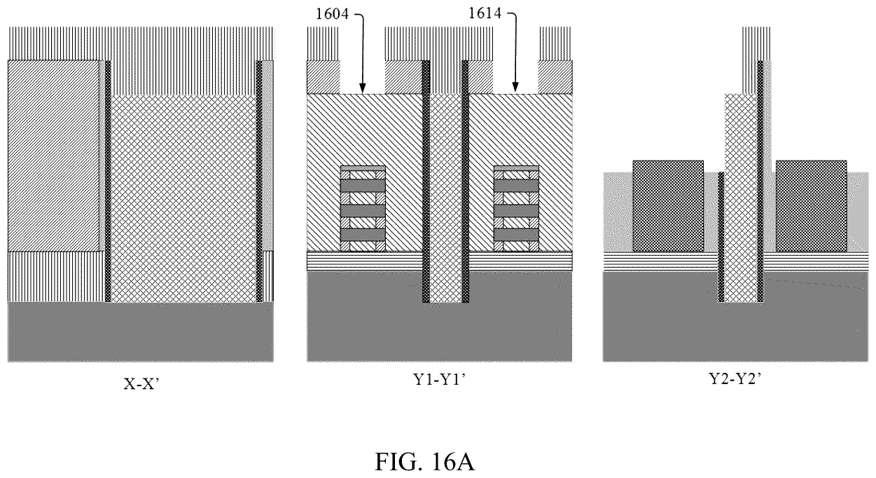

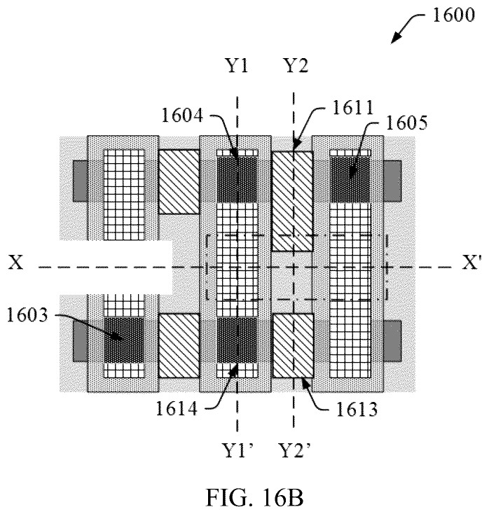

FIG. 16A illustrates example, non-limiting cross-sectional views of a gate contact opening step in a semiconductor device fabrication process in accordance with one or more embodiments described herein. Repetitive description of like elements and/or processes employed in respective embodiments is omitted for sake of brevity. ILD and silicon nitride layers are removed to form gate contacts, identified as 1604 and 1614.

FIG. 16B illustrates an example, non-limiting top view 1600 of a gate contact patterning step in a semiconductor device fabrication process in accordance with one or more embodiments described herein. Repetitive description of like elements and/or processes employed in respective embodiments is omitted for sake of brevity. Exposed gate contacts are identified as 1603, 1604, 1605 and 1614, and exposed source/drain contacts are identified as 1611 and 1613.

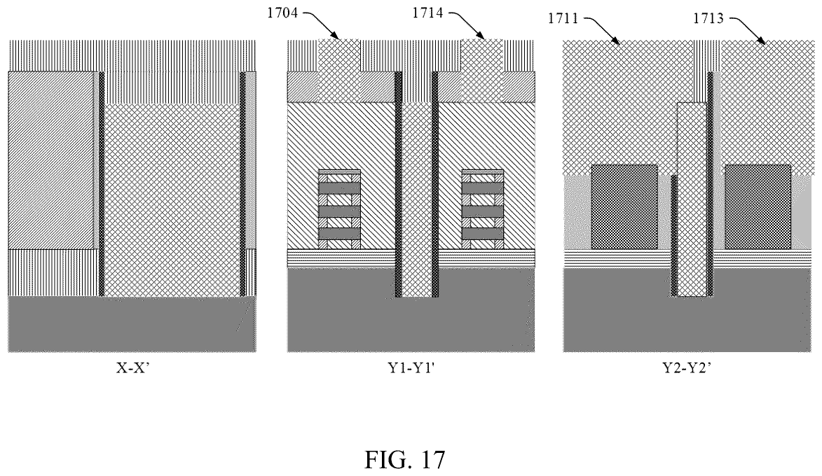

FIG. 17 illustrates example, non-limiting cross-sectional views of a metallization step in a semiconductor device fabrication process in accordance with one or more embodiments described herein. Repetitive description of like elements and/or processes employed in respective embodiments is omitted for sake of brevity. The voids created by S/D contact and gate contact patterning are filled with conductive metal, which may be cobalt, tungsten or another metal. The resulting gate contacts are identified as 1704 and 1714, and the resulting S/D contacts are identified as 1711 and 1713.

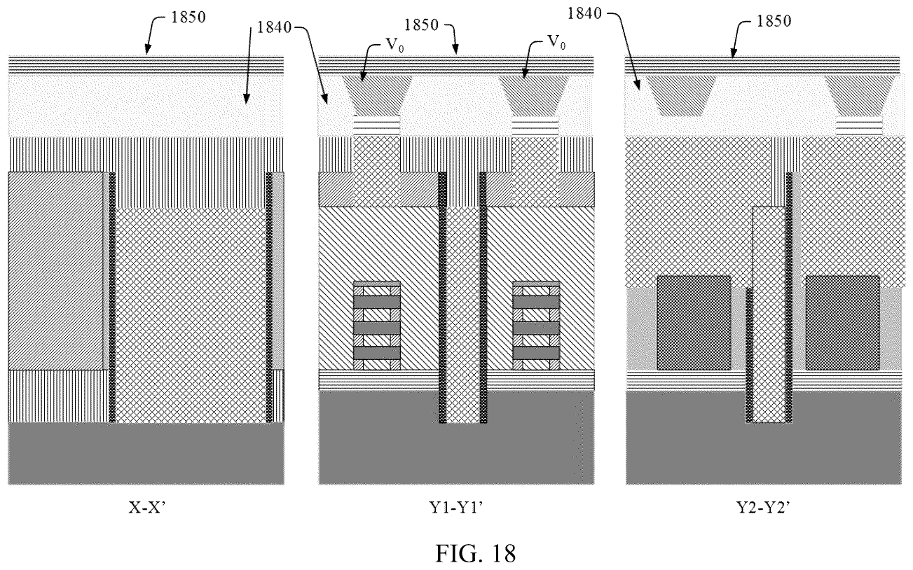

FIG. 18 illustrates example, non-limiting cross-sectional views of a step comprising forming BEOL levels in a semiconductor device fabrication process in accordance with one or more embodiments described herein. Repetitive description of like elements and/or processes employed in respective embodiments is omitted for sake of brevity. Within an ILD layer, identified as 1840, vias identified as V₀ are formed and metallized, and BEOL levels, identified as 1850, are formed above the ILD layer and vias. As shown without much detail in FIG. 18, the vias are connected to one or more metal layers of the BEOL level.

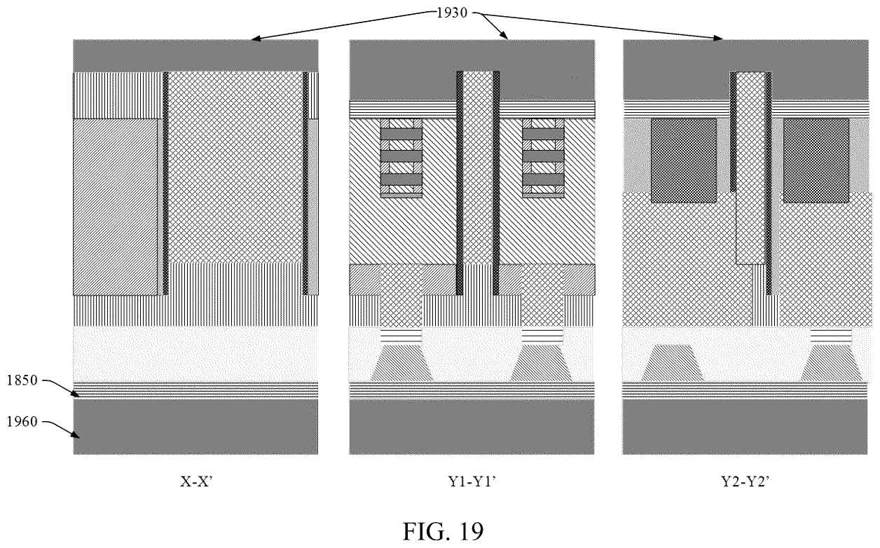

FIG. 19 illustrates example, non-limiting cross-sectional views of a step comprising wafer bonding, flipping and grinding the new “front side” in a semiconductor device fabrication process in accordance with one or more embodiments described herein. Repetitive description of like elements and/or processes employed in respective embodiments is omitted for sake of brevity. A carrier wafer identified as 1960 is bonded to the BEOL 1850, then the semiconductor device is flipped, and the silicon substrate 1930, which was first identified as 330 in FIG. 3B, is thinned down.

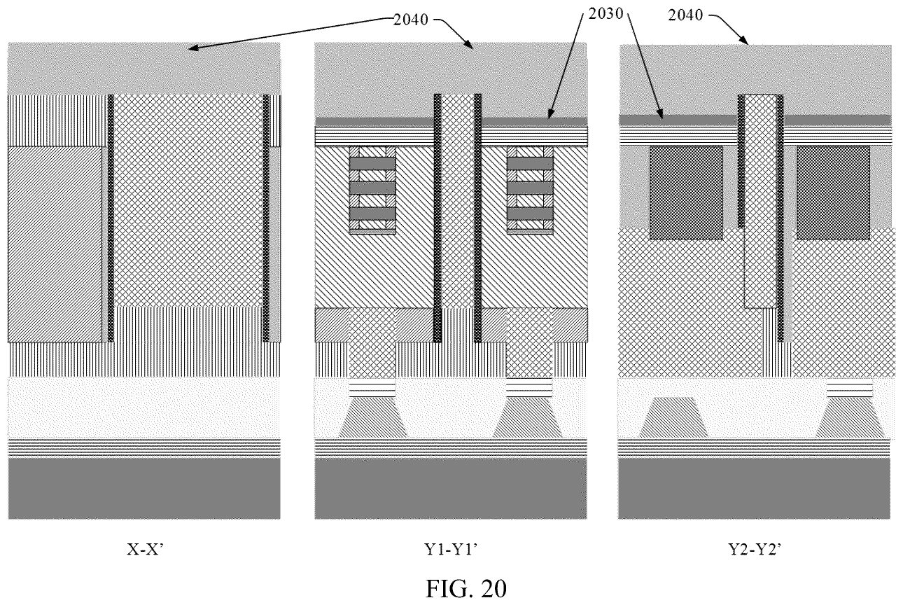

FIG. 20 illustrates example, non-limiting cross-sectional views of a step comprising recessing a silicon layer in a semiconductor device fabrication process in accordance with one or more embodiments described herein. Repetitive description of like elements and/or processes employed in respective embodiments is omitted for sake of brevity. Much of the silicon substrate is removed, with a layer remaining which is visible in views Y1-Y1′ and Y2-Y2′ and identified as 2030. An ILD layer is deposited, identified as 2040, and then planarized with a CMP process.

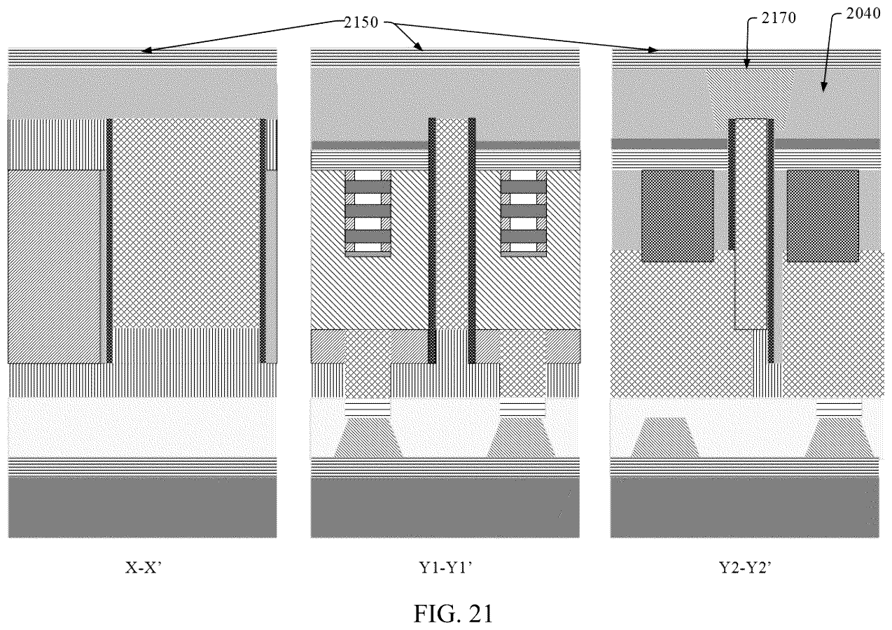

FIG. 21 illustrates example, non-limiting cross-sectional views of a metallization step comprising forming a BSPR and additionally BEOL levels in a semiconductor device fabrication process in accordance with one or more embodiments described herein. Repetitive description of like elements and/or processes employed in respective embodiments is omitted for sake of brevity. Within the ILD layer previously identified as 2040, a back-side power rail (BSPR) identified as 2170 is formed and metallized. Then, BEOL levels are formed, identified as 2150.

FIG. 21 may be viewed in conjunction with FIG. 1 as an embodiment of the semiconductor device with a VBPR and via spacer.

After the metallization and in the subsequent process flow steps, it can be observed that the source/drain contact identified as CA 111 and CA 1411 connects to the back-side power rail 2170 through the VBPR identified as 1515, since no via spacer separates the VBPR from that source/drain contact. It can also be observed that the gate contacts identified as 1704 and 1714 do not connect to the back-side power rail, since a via spacer identified as 125 and 625 prevents conduction between the gates and the VBPR. All of the gate contacts do, however, connect after metallization and subsequent process flow steps to the FEOL signal rail region, as illustrated in FIG. 18 by V₀ and 1850.

As discussed in one or more embodiments herein, patterning is the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light. The exposed regions are then washed away by a developer solution. After etching or other processing, the remaining photoresist is removed. After transferring the pattern, the patterned photoresist is removed utilizing resist stripping processes, such as wet chemical clean or ashing. Ashing can be used to remove a photoresist material, amorphous carbon, or organic planarization (OPL) layer. Ashing is performed using a suitable reaction gas, for example, O₂, N₂, H₂/N₂, O₃, CF₄, or any combination thereof. Patterning also includes electron-beam lithography, nanoimprint lithography, and reactive ion etching.

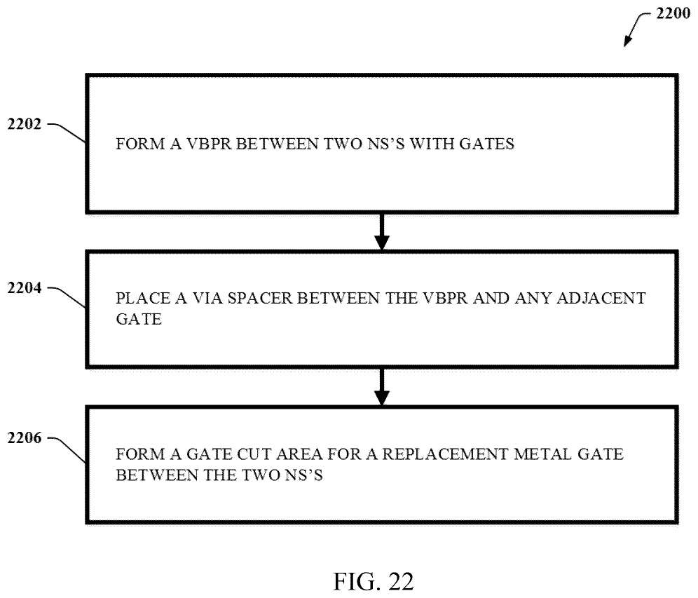

FIG. 22 illustrates a flow diagram of an example, non-limiting method 2200 in accordance with one or more embodiments described herein. Repetitive description of like elements and/or processes employed in respective embodiments is omitted for sake of brevity.

At 2202, the non-limiting method 2200 can comprise forming a VBPR on a semiconductor device, where the VBPR is located between two NS's.

At 2204, the non-limiting method 2200 can comprise placing a via spacer within the VBPR.

At 2206, the non-limiting method 2200 can comprise forming a gate cut area for a replacement metal gate between the two NS's.

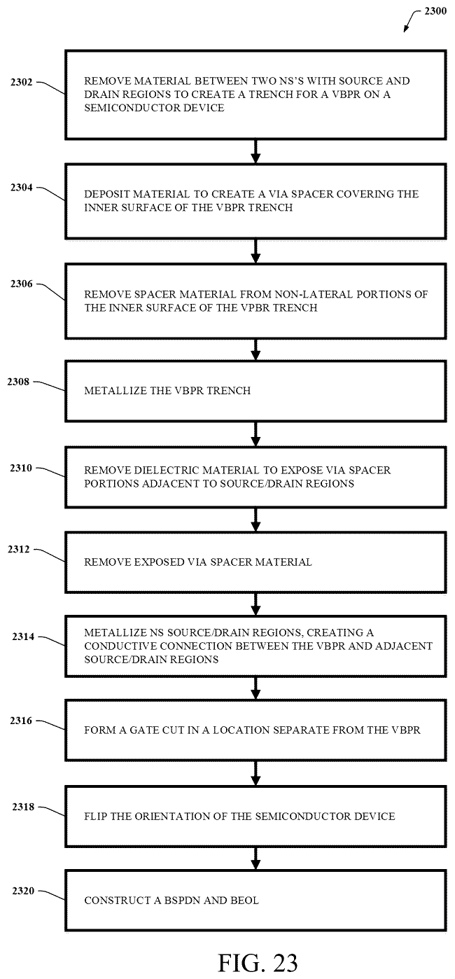

FIG. 23 illustrates a flow diagram of an example, non-limiting method 2300 in accordance with one or more embodiments described herein. Repetitive description of like elements and/or processes employed in respective embodiments is omitted for sake of brevity.

At 2302, the non-limiting method 2300 can comprise removing material between two NS's to create a trench for a VBPR on a semiconductor device.

At 2304, the non-limiting method 2300 can comprise depositing material to create a via spacer covering the inner surface of the VBPR trench.

At 2306, the non-limiting method 2300 can comprise removing via spacer material from non-lateral portions of the inner surface of the VBPR trench.

At 2308, the non-limiting method 2300 can comprise metallizing the VBPR trench.

At 2310, the non-limiting method 2300 can comprise removing dielectric material to expose via spacer portions which are adjacent to source/drain regions.

At 2312, the non-limiting method 2300 can comprise removing the exposed via spacer material.

At 2314, the non-limiting method 2300 can comprise metallizing the source/drain regions on the FET's, creating a conductive connection between the VBPR and adjacent source/drain regions.

At 2316, the non-limiting method 2300 can comprise forming a gate cut in a location on the semiconductor device which is separate from the VBPR's location.

At 2318, the non-limiting method 2300 can comprise flipping the orientation of the semiconductor device, from front-end-on-top to back-end-on-top.

At 2320, the non-limiting method 2300 can comprise constructing a BSPDN, which can be a BSPR, and a BEOL.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

It is, of course, not possible to describe every conceivable combination of methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device, comprising:
a via-to-backside power rail (VBPR) located between a first-nano sheet (NS) and a second NS;
two or more gates, each gate being connected to one or more of the first and second NS's; and
a via spacer located between the VBPR and each gate which is adjacent to the VBPR, wherein the via spacer prevents shorting between the VBPR and each adjacent gate.

2. The semiconductor device of claim 1, further comprising a silicon nitride filled gate cut area located between the first and second NS's, wherein the VBPR is located outside of the silicon nitride filled gate cut area.

3. The semiconductor device of claim 2, further comprising:
one or more source regions and drain regions, each source region and drain region being connected to a contact on a frontside of the device; and
no via spacer separating the VBPR and an adjacent source or drain region, allowing the VBPR to be conductively connected to the adjacent source or drain region.

4. The semiconductor device of claim 3, further comprising:
a backside power delivery network on a backside of the device, wherein the backside power delivery network is connected to the VBPR.

5. The semiconductor device of claim 4, wherein the via spacer comprises one or more layers of silicon oxycarbide (SiOC).

6. The semiconductor device of claim 5, wherein the VBPR comprises a top surface, a bottom surface, and a plurality of lateral surfaces, and wherein the via spacer covers each lateral surface of the VBPR except for areas where the VBPR is adjacent to a source region or drain region.

7. The semiconductor device of claim 1, further comprising:
one or more source regions and drain regions, each source region and drain region being connected to a contact on a frontside of the device; and
no via spacer separating the VBPR and an adjacent source or drain region, allowing the VBPR to be conductively connected to the adjacent source or drain region.

8. The semiconductor device of claim 1, further comprising:
a backside power delivery network on a backside of the device, wherein the backside power delivery network is connected to the VBPR.

9. The semiconductor device of claim 1, wherein the via spacer comprises one or more layers of silicon oxycarbide (SiOC).

10. The semiconductor device of claim 1, wherein the VBPR comprises a top surface, a bottom surface, and a plurality of lateral surfaces, and wherein the via spacer covers each lateral surface of the VBPR except for areas where the VBPR is adjacent to a source region or drain region.

11. A method, comprising steps of:
forming a via-to-back power rail (VBPR) between a first-nanosheet (NS) of a field effect transistor (FET) and a second NS; and
placing a via spacer between the VBPR and any adjacent gate, wherein the via spacer prevents shorting between the VBPR and each adjacent gate.

12. The method of claim 11, further comprising performing a step of forming a gate cut area for a replacement metal gate between the first and second NS's after completion of the steps of forming a VBPR and placing a via spacer.

13. The method of claim 11, wherein each NS further comprises one or more gates, source regions and drain regions; and
wherein no via spacer separates the VBPR from an adjacent source region or drain region, allowing the VBPR to be conductively connected to the adjacent source or drain region.

14. The method of claim 11, wherein the via spacer comprises one or more layers of silicon oxycarbide (SiOC).

15. The method of claim 11, wherein a backside power delivery network (BSPDN) is connected to the VBPR, wherein the BSPDN is located on a backside of the device.

16. The method of claim 12, wherein the VBPR and the gate cut area do not overlap.

17. A method for fabricating a semiconductor device with a via-to-back power rail (VBPR) the method comprising:
removing material to create a trench with an inner surface for a VBPR, wherein the VBPR trench has a location which is between first and second NS's, wherein each NS has one or more of gates, source regions and drain regions;
depositing material to create a via spacer which covers the inner surface of the VBPR trench;
removing via spacer material from non-lateral portions of the inner surface of the VBPR trench;
metallizing the VBPR trench;
removing dielectric material to expose one or more via spacer portions which are adjacent to one or more of the source regions and drain regions;
removing exposed via spacer material; and
metallizing the source regions and drain regions, creating a conductive connection between the VBPR and adjacent source and drain regions.

18. The method of claim 17, wherein the semiconductor device has a front side and a back side, and wherein the semiconductor device has an orientation of front side on top, further comprising:
flipping the orientation of the semiconductor device to back side on top; and
constructing a backside power delivery network (BSPDN) and back end of line (BEOL).

19. The method of claim 17, further comprising:
forming late gate cuts in a location on the semiconductor device which is separate from the VBPR location.

20. The method of claim 17, further comprising:
wherein the via spacer material comprises one or more layers of silicon oxycarbide (SiOC).
